(19) United States
(12) Patent Application Publication
(10) Pub. No.: US 2020/0075035 A1
(43) Pub. Date: Mar. 5, 2020

(54) Sound Shield Device

(71) Applicants: Thomas Garth, III, Spring, TX (US); David Lee Higdon, Georgetown, TX (US)

(72) Inventors: Thomas Garth, III, Spring, TX (US); David Lee Higdon, Georgetown, TX (US)

(21) Appl. No.: 16/118,047

(22) Filed: Aug. 30, 2018

(51) Int. Cl. G10L 21/0272; H02P 8/22; H03K 17/95; H04R 1/20; G10L 15/20

(52) U.S. Cl. CPC G10L 21/0272; H02P 8/22; G10L 2021/02087; H04R 1/20; G10L 15/20; H03K 17/9517

(57) ABSTRACT

A soundstage device to generate a random noise signal may include a container to include a virtual assistant. The container may include a base to mount the virtual assistant and a lid to connect to the base; the lid may be movable between a first position and a second position, and the lid may include a random noise generator to generate the random noise signal.

### FIELD OF THE INVENTION

The present invention relates to a device to generate random noise signals and more particularly to a device to limit the ability of a virtual assistant to listen to the voice of a user.

### BACKGROUND

Virtual assistants are extremely popular and becoming more so. The virtual assistant can record instructions, commands and data from a user and access the Internet to achieve a response to the instructions, commands and data. These virtual assistants have sensitive listening capabilities and can listen when the user believes that the virtual assistant has been turned off.

Privacy concerns have been raised about the use of these virtual systems. It is quite likely that all of the instructions are recorded remotely and may be used at some future time for the benefit or detriment of the user.

A method or apparatus in order to negate the recording of instructions has been sought to eliminate or mitigate the privacy concerns, but to date, no solution has been found.

### SUMMARY

A soundstage device to generate a random noise signal may include a container to include a virtual assistant. The container may include a base to mount the virtual assistant and a lid to connect to the base; the lid may be movable between a first position and a second position, and the lid may include a random noise generator to generate the random noise signal.

The first position may be a raised position.

The second position may be a lowered position.

The random noise generator may include a voice recognition processor to accept commands from the user.

The random noise generator may include a stepper drive to raise and lower the lid.

The random noise generator may include a stepper motor.

The random noise generator may include a Hall-effect switch.

The random noise generator may include a power control circuit.

The random noise generator may include a power regulator.

### BRIEF DESCRIPTION OF THE DRAWINGS

The invention may be understood by reference to the following description taken in conjunction with the accompanying drawings, in which, like reference numerals identify like elements, and in which:

FIG. 1 illustrates a circuit diagram of the present invention;

FIG. 2 illustrates a side view of the container and virtual assistant of the present invention in an open position;

FIG. 3 illustrates a front view of the container of the present invention in a closed position;

FIG. 4 illustrates a front view of the container of the present invention in an open position;

FIG. 5 illustrates a top view of the container of the present invention;

FIG. 6 illustrates a bottom view of the container of the present invention;

FIG. 7 illustrates a front view of another embodiment of the present invention.

### DETAILED DESCRIPTION

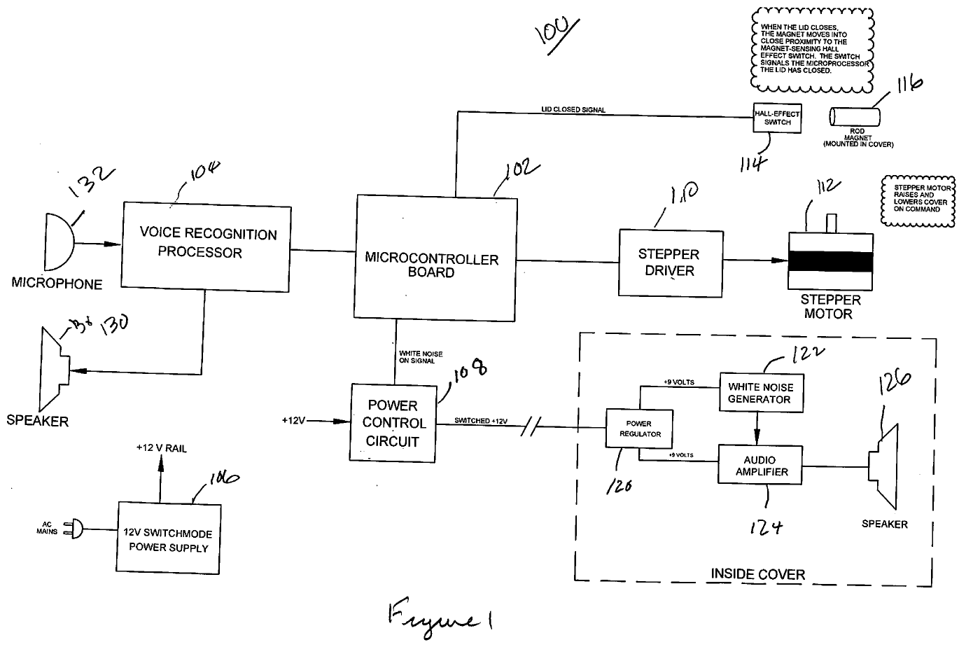

The Sound Shield device 100 of the present invention as shown in FIG. 1 may include a main power supply circuit 106 receiving power from AC main such as the AC power from being plugged in to the household power. This main power supply circuit 106 supplies a +12V power control circuit 108 to all electronic assemblies of the sound Shield device 100 of the present invention. This main power supply circuit 108 may be commercially available. The main power supply circuit 108 may include multiple linear power regulators (LM78xx) circuits 120 which may provide multiple output voltages such as +5V and +9V to the boards used to mount the various circuits of the present invention. The 9 V power may be supplied to a random noise generator 122 (or a white noise generator) which may generate random noise in order to overcome the personal assistant by saturating the personal assistant with a great multitude of signals of different frequencies. A 5V power may be applied to an audio amplifier in order to bias the components of the audio amplifier 124. The random noise signal supplied by the random noise generator 122 (or the white noise generator) is amplified by the audio amplifier 124 and the output of the audio amplifier 124 is connected to speaker 126 to output the signal supplied by the random noise generator 122 and being amplified by the audio amplifier 124.

The CPU in the present invention may be a microcontroller 102 which may be an Atmel ATMega 2560 which is contained with a board which may be an Arduino Mega2560. Mounted onto the expansion connectors are a voice recognition processor 104 such as an Audeme MOVI, and a daughter board with both the stepper motor driver circuit 110 which may be an Allegro A3957 and an audio amplifier which may be an 1 W class D audio amplifier. The voice recognition processor 104 may be connected to a speaker 130 and a microphone 132. The stepper driver circuit 110 is connected to the stepper motor 112 which may be a NEMA 17 stepper motor and which lifts the lid of the container upon command from the user and is activated by the voice recognition processor 104. The audio amplifier which may be class D may be used to play a voice message and/or que beeps to the user.

One port pin of the microcontroller 102 such as the Atmel microcontroller is connected to a power control circuit 108 including a bipolar transistor and a P Channel power FET which, upon command by the microcontroller 102, enables the +12V rail to be connected to the upper assembly as appropriate. This +12V rail operates the random noise generator 122 and associated audio amplifier 124. When energized, the rail activates the random noise generator 122 and audio amplifier 124.

The upper assembly positioned inside the cover of the box includes a regulator assembly 120 having a first linear regulator which may be a +5V (LM7805) and a second linear regulator which may be a +9V (LM7809). The second linear regulator is used to provide a highly bypassed and isolated power rail for the random noise generator 122. The first linear regulator such as +5V is used to provide power to the 500 mW linear audio amplifier 124.

The random noise generator 122 includes a reverse biased transistor junction which is driven slightly into the breakdown region of the reversed biased transistor junction. This reversed biased transistor junction becomes the primary element of a random noise source 122. The output of this source is amplified using a high impedance amplifier 124 which is connected to and drives an emitter follower to drive the input of the audio amplifier 124. Due to the high gain of the bipolar transistor, amplifier may be connected to the output of the noise source and decoupling and isolation should be provided, hence the use of the second linear regulator (+9 V).

Due the broad band nature of the noise source, spectral shaping of the random noise is provided to limit the bandwidth of the random noise to avoid overloading the audio amplifier with frequencies that are out of the response range and also cannot be reproduced by the speaker which may be a 2 inch speaker. This is adjustable.

The audio amplifier may be an integrated circuit based (Texas Instruments LM380) design. The input of the audio amplifier is connected to a potentiometer providing noise volume control. The output drives the speaker which fills the inside of the enclosure of the container with the desired random noise.

The power which may be +12V to the upper assembly is controlled by the aforementioned FET switch and port pin of the microcontroller.

In order to provide feedback to the microcontroller as to the position of the cover/lid 204 of the container 202 (SoundShield), a Hall Effect switch 114 and Neodymium magnet are employed. The Hall Effect switch 114 is affixed to a small printed circuit board in the base of the container and the Neodymium magnet 116 is affixed to the cover/lid of the container. The output of the Hall Effect switch 114 is connected to a port pin of the microcontroller and is read at boot and during any motion operation of the lid.

Voice recognition is provided by the voice recognition processor 104 such as Audeme MOVI to allow control of the operation of the device 100. The voice recognition processor 104 may include an ARM Microcontroller running embedded open source Linux. Voice recognition is performed offline via additional open source software running under for example the Linux operating system. The board has a microphone input, amplification and basic signal processing, and a CODEC a device or program that compresses data to enable faster transmission and decompresses received data to digitize the sound received by the microphone. The digitized audio is processed by voice recognition software.

A word library is loaded during boot which contains the attention word (called a “callsign”) by the providers of the voice recognition processor 104 (MOVI) and action verbs. This is discussed in detail in the following section.

The voice recognition processor 104 such as MOVI is interfaced to the Arduino board via a serial interface. A library is provided by voice recognition processor 104 Audeme which aids in interfacing the user software to the voice recognition processor 104 MOVI. This library receives data from the voice recognition processor 104 MOVI and passes the results to the main code of the voice recognition processor 104.

Upon this event, the microcontroller 102 receives the information from the voice recognition processor 104 MOVI received from the voice interface that the user requests either to open or close the cover, and the stepper motor controller 110 is activated to perform the desired action by rotating the stepper motor 112 either clockwise or counter clockwise which will raise or lower the cover/lid.

A lead screw is attached to the shaft of the stepper motor 112 via a shaft coupler. A follower to cooperate with the lead screw is attached to the cover which makes it stationary. The rotation of the lead screw will provide a lifting force to the cover which will open it. To lower the cover, the motor 112 is reversed which will smoothly lower it. The Hall Effect switch 114 is monitored during closure and will trigger the motor 112 to stop with the cover being fully seated upon the base.

The cover is aligned using two vertical stainless steel rods 218. These rods provide both alignment between the cover and base and anti rotation against the force of the rotating lead screw.

These rods 218 are fitted into machined aluminum guides pressed into the cover which reduce friction during operation.

### Operation:

At power up, the microcontroller enters a boot up sequence. This sequence is as follows:
1. Configure all port pins.
2. Initialize the voice recognition module Audeme MOVI.
3. Set and confirm the word recognition sequence in the voice recognition module MOVI
4. Read the position of the cover of the Hall Effect switch and attempts to close the cover if open.
5. Enter the foreground loop.

The foreground loop monitors the voice recognition module MOVI waiting for it to recognize an action sequence from the user. The action sequence includes the attention word spoken by the user, a ready beep from the SoundShield, and the user speaking a desired action. The attention word is fixed and recognized entirely inside the voice recognition module MOVI.

The words are sent to the microcontroller of the Arduino board which compares them against an internal library including all possible combinations of valid actions. By comparing to different sequences of words both in and out of order, the SoundShield can respond to a variety of commands. Commands such as “Open box”, “Open it”, “Open the box”, etc. are recognized. This approach of the present invention allows the user to think naturally instead of having to remember an exact word sequence.

Each group of words is assigned to a desired action, i.e. opening the cover or closing it. When an action is recognized and the decision is made to move the cover, the stepper motor is enabled and turned in the appropriate direction. If the cover is being opened, the +12V rail feeding the random noise generator is turned off and the cover is opened. When the cover is commanded to close the +12V is turned back on after complete closure.

### Enhancements:

A production level device could incorporate a WLAN interface which can be configured to a household wireless access point and could talk to other Sound Shield devices 100 in the home. For security, the gateway in the routing tables of the WLAN interfaces are disabled preventing them being accessed outside the local area network.

In an example implementation, one device 100 is assigned to a master role. The other sound Shield devices 100 are linked as slaves devices 100 to the master device 100. The master device 100 can be placed in a first location such as either the living room or bedroom. Upon command to the master device 100 the slave devices 100 can be commanded to close and cease accepting commands. Each slave device 100 will monitor the master device 100 for any change in operation, or if in the absence of the master device 100, each slave device 100 will resume normal operation.

One example could be a virtual assistant 208 with the slave device 100 located in a child's bedroom which can be locked down and disabled providing a parent control through the master device 100. Another example would be the child is using the virtual assistant 208 in doing homework. At either a predetermined time (bedtime in this example) or by command by the parent, the virtual Assistant associated with the slave device 100 is disabled and locked down ensuring privacy and controlling the child's usage of the virtual assistant 208.

This technology could be extended to perhaps a smartphone application that allows control of all Voice Assistants 208 in the home.

The prototype incorporates a rotary motor and lead screw arrangement. A different approach could be constructed from a linear actuator operated by a lift cable and capstan attached to a small motor.

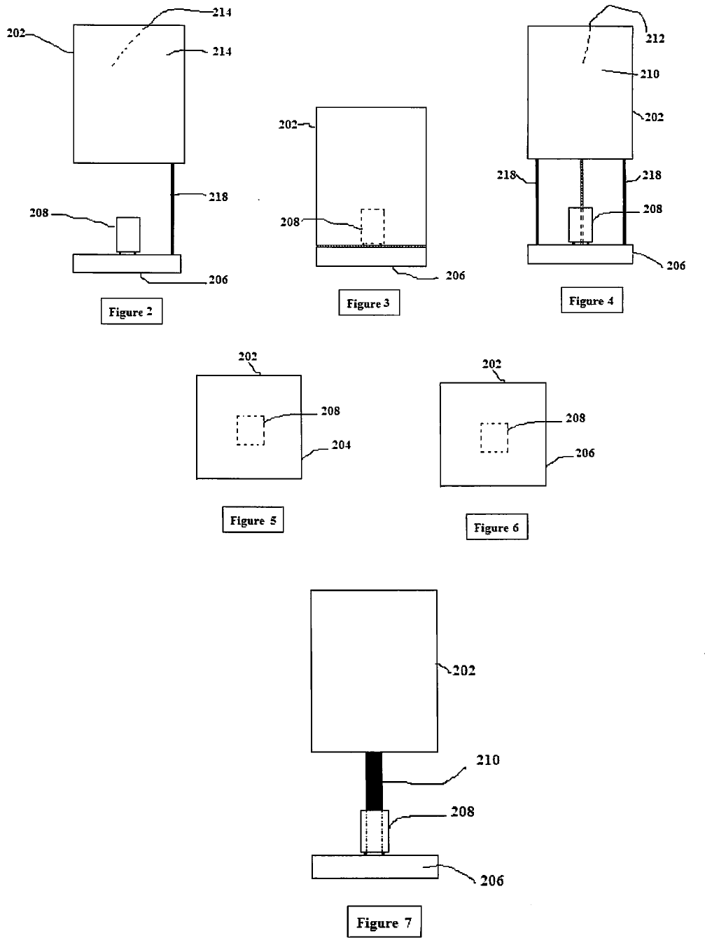

FIGS. 2-6 illustrates the container 202 and the virtual assistant 208, and the container 202 includes a lid 204 to cooperate with a base 206. The virtual assistant 208 may be positioned in the base 206 and the Sound Shield device 100 may be positioned within the lid 204. The lid 204 is movable between a closed position where the periphery of the lid 204 contacts the base 206 where the random noise generator 122 generates random noise to prevent the operation of the virtual assistant 208. The lid 204 may be movable to an open position where the random noise generator 122 does not generate random noise to allow the uninhibited operation of the virtual assistant 208. The lid 204 may include a front wall 210, an opposed back wall 212, and a pair of opposed side walls 214 which may connect the front wall 210 to the back wall 212. The front wall 210, the back wall 212 and the pair of opposed side walls 214 may define a cavity 216 to enclose the virtual assistant 208 when the lid 204 is in a closed position. The cavity 216 is open around the periphery of the lid 204. The base 206 may include a pair of vertical rails 218 to guide the lid 204 as the lid 204 moves between the open position and the closed position.

FIG. 7 illustrates a another embodiment of the present invention, and the container 202 may be raised and lowered over the virtual assistant 208 by a cord being connected to a pulley or a gang of pulleys which raise and lower the container 202 being guided by an aluminum square tube 220 which may cooperate with a channel formed in the interior surface of the container 202, eliminating the need for opposing rods.

The cord may be connected to a shaft of a motor allowing the motor to raise the container 202 by turning in a first direction and to lower the container 202 by turning in a second direction.

A thin layer of insulation may be formed inside the cover of the container to prevent the random noise from leaking out and annoying the person using the device. Without the thin layer of insulation, a soft hiss may be generated when the container is closed and the user might find it objectionable.

While the invention is susceptible to various modifications and alternative forms, specific embodiments thereof have been shown by way of example in the drawings and are herein described in detail. It should be understood, however, that the description herein of specific embodiments is not intended to limit the invention to the particular forms disclosed.

1. A soundstage device to generate a random noise signal, comprising:
a container to include a virtual assistant;
the container including a base to mount the virtual assistant and a lid to connect to the base and being movable between a first position and a second position; wherein the lid includes a random noise generator to generate the random noise signal.

2) A soundstage device to generate a random noise signal as in claim 1, wherein the first position is a raised position.

3) A soundstage device to generate a random noise signal as in claim 1, wherein the second position is a lowered position.

4) A soundstage device to generate a random noise signal as in claim 1, wherein the random noise generator includes a voice recognition processor to accept commands from the user.

5) A soundstage device to generate a random noise signal as in claim 1, wherein the random noise generator includes a stepper drive to raise and lower the lid.

6) A soundstage device to generate a random noise signal as in claim 1, wherein the random noise generator includes a stepper motor.

7) A soundstage device to generate a random noise signal as in claim 1, wherein the random noise generator includes a Hall-effect switch.

8) A soundstage device to generate a random noise signal as in claim 1, wherein the random noise generator includes a power control circuit.

9) A soundstage device to generate a random noise signal as in claim 1, wherein the random noise generator includes a power regulator.
